(19) United States
(12) Patent Application Publication
(10) Pub. No.: US 2025/0194085 A1
(43) Pub. Date: Jun. 12, 2025

(54) SEMICONDUCTOR DEVICE HAVING STI REGION

(71) Applicant: MICRON TECHNOLOGY, INC., BOISE, ID (US)

(72) Inventor: Kunihiro Tsubomi, Higashihiroshima (JP)

(73) Assignee: MICRON TECHNOLOGY, INC., BOISE, ID (US)

(21) Appl. No.: 19/051,876

(22) Filed: Feb. 12, 2025

Related U.S. Application Data
(62) Division of application No. 17/202,146, filed on Mar. 15, 2021, now Pat. No. 12,238,924.

(51) Int. Cl. H10B 12/00; H01L 21/02; H01L 21/3105; H01L 21/311; H01L 21/762; H10D 62/10

(52) U.S. Cl. CPC H10B 12/50; H01L 21/02164; H01L 21/0217; H01L 21/31053; H01L 21/31116; H01L 21/76224; H10B 12/09; H10D 62/115

(57) ABSTRACT

An example apparatus includes a semiconductor substrate including first and second circuit regions, a first trench extending in a first direction and formed between the first and second circuit regions, wherein the first trench includes a first inner wall positioned on the first circuit region side and a second inner wall positioned on the second circuit region side, and a plurality of second trenches extending in a second direction different from the first direction and formed in the first circuit region such that the second trench communicates with the first trench at the first inner wall; and a first insulating film formed on the first and second inner walls such that the second inner wall is covered with the first insulating film without being exposed.

### CROSS-REFERENCE TO RELATED APPLICATIONS

This application a divisional of U.S. patent application Ser. No. 17/202,146, filed Mar. 15, 2021, which is incorporated by reference herein in its entirety and for all purposes.

### BACKGROUND

In a semiconductor device such as a DRAM (Dynamic Random Access Memory), there is a case where a memory cell array region and a peripheral circuit region are separated by an STI (Shallow Trench Isolation). The STI is filled with an insulating material such as a silicon oxide. It is desirable that a level difference between the surface of the STI formed of the insulating material such as a silicon oxide and the surface of the memory cell array region to be small. Meanwhile, it is preferable that the surface of the STI protrudes from the surface of the peripheral circuit region. The reason is that the top part of an inner wall of the STI positioned on the side of the peripheral circuit region is exposed. A conducting material constituting a wiring pattern is accumulated in the exposed part due to preprocessing for forming a gate dielectric film in the peripheral circuit region if the surface of the STI is not protruded from the surface of the peripheral circuit region.

### BRIEF DESCRIPTION OF THE DRAWINGS

FIG. 1A is a partial schematic plan view of a semiconductor device according to the present disclosure, and FIG. 1B is a schematic cross-section along a line A-A shown in FIG. 1A.

FIG. 2A is a partial schematic plan view for a manufacturing process of the semiconductor device according to the present disclosure, and FIG. 2B is schematic cross-sections along a line A-A shown in FIG. 2A;

FIG. 3A is a partial schematic plan view for a manufacturing process of the semiconductor device according to the present disclosure, and FIG. 3B is schematic cross-sections along a line A-A shown in FIG. 3A;

FIG. 4A is a partial schematic plan view for a manufacturing process of the semiconductor device according to the present disclosure, and FIG. 4B is schematic cross-sections along a line A-A shown in FIG. 4A;

FIG. 5A is a partial schematic plan view for a manufacturing process of the semiconductor device according to the present disclosure, and FIG. 5B is schematic cross-sections along a line A-A shown in FIG. 5A;

FIG. 6A is a partial schematic plan view for a manufacturing process of the semiconductor device according to the present disclosure, and FIG. 6B is schematic cross-sections along a line A-A shown in FIG. 6A;

FIG. 7A is a partial schematic plan view for a manufacturing process of the semiconductor device according to the present disclosure, and FIG. 7B is schematic cross-sections along a line A-A shown in FIG. 7A;

FIG. 8A is a partial schematic plan view for a manufacturing process of the semiconductor device according to the present disclosure, and FIG. 8B is schematic cross-sections along a line A-A shown in FIG. 8A;

FIG. 9A is a partial schematic plan view for a manufacturing process of the semiconductor device according to the present disclosure, and FIG. 9B is schematic cross-sections along a line A-A shown in FIG. 9A;

FIG. 10A is a partial schematic plan view for a manufacturing process of the semiconductor device according to the present disclosure, and FIG. 10B is schematic cross-sections along a line A-A shown in FIG. 10A;

FIG. 11A is a partial schematic plan view for a manufacturing process of the semiconductor device according to the present disclosure, and FIG. 11B is schematic cross-sections along a line A-A shown in FIG. 11A;

FIG. 12A is a partial schematic plan view for a manufacturing process of the semiconductor device according to the present disclosure, and FIG. 12B is schematic cross-sections along a line A-A shown in FIG. 12A;

FIG. 13A is a partial schematic plan view for a manufacturing process of the semiconductor device according to the present disclosure, and FIG. 13B is schematic cross-sections along a line A-A shown in FIG. 13A;

FIG. 14A is a partial schematic plan view for a manufacturing process of the semiconductor device according to the present disclosure, and FIG. 14B is schematic cross-sections along a line A-A shown in FIG. 14A;

FIG. 15A is a partial schematic plan view for a manufacturing process of the semiconductor device according to the present disclosure, and FIG. 15B is schematic cross-sections along a line A-A shown in FIG. 15A;

FIG. 16A is a partial schematic plan view for a manufacturing process of the semiconductor device according to the present disclosure, and FIG. 16B is schematic cross-sections along a line A-A shown in FIG. 16A;

FIG. 17A is a partial schematic plan view for a manufacturing process of the semiconductor device according to the present disclosure, and FIG. 17B is schematic cross-sections along a line A-A shown in FIG. 17A;

FIG. 18A is a partial schematic plan view for a manufacturing process of the semiconductor device according to the present disclosure, and FIG. 18B is schematic cross-sections along a line A-A shown in FIG. 18A;

FIG. 19A is a partial schematic plan view for a manufacturing process of the semiconductor device according to the present disclosure, and FIG. 19B is schematic cross-sections along a line A-A shown in FIG. 19A; and

FIG. 20A is a partial schematic plan view for a manufacturing process of the semiconductor device according to the present disclosure, and FIG. 20B is schematic cross-sections along a line A-A shown in FIG. 20A.

### DETAILED DESCRIPTION

Various embodiments of the present invention will be explained below in detail with reference to the accompanying drawings. The following detailed description refers to the accompanying drawings that show, by way of illustration, specific aspects, and embodiments in which the present invention may be practiced. These embodiments are described in sufficient detail to enable those skilled in the art to practice the present invention. Other embodiments may be utilized, and structural, logical, and electrical changes may be made without departing from the scope of the present invention. The various embodiments disclosed herein are not necessary mutually exclusive, as some disclosed embodiments can be combined with one or more other disclosed embodiments to form new embodiments.

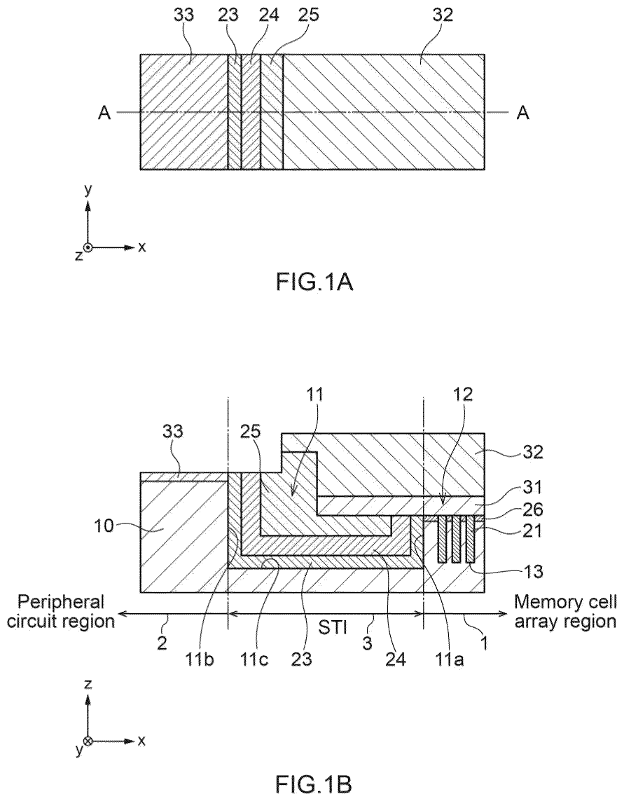

A semiconductor device according to the present disclosure is a semiconductor memory device such as a DRAM and includes a semiconductor substrate 10 divided into a memory cell array region 1, a peripheral circuit region 2, and an STI region 3 as shown in FIG. 1B. The STI region 3 has a configuration in which insulating films 23 to 25 are embedded in a trench 11 formed on the semiconductor substrate 10. The insulating film 23 may include a silicon oxide, the insulating film 24 may include a silicon nitride, and the insulating film 25 may include a SOG (Spin-On-Glass) material. The STI region 3 extends in a y direction and is positioned between the memory cell array region 1 and the peripheral circuit region 2. Different trenches 12 and 13 are also formed on the semiconductor substrate 10. The trench 12 extends in an x direction over the memory cell array region 1 and the STI region 3. Although only one trench 12 is illustrated in a cross-section shown FIG. 1B, in practice a plurality of the trenches 12 extending in the x direction are arrayed in the y direction. A word line 31 is partially embedded in an associated one of the trenches 12. A top part of each of the word lines 31 is covered with an insulating film 32. An insulating film 21 including a silicon oxide is embedded in the inner parts of the trenches 13 and functions as a STI region for cell transistors. In the cross-section shown in FIG. 1B, the surface of the semiconductor substrate 10 in the peripheral circuit region 2 is covered with an insulating film 33. The insulating film 33 is a gate dielectric film of a transistor formed in the peripheral circuit region 2.

The trench 11 has inner walls 11a and 11b, and a bottom surface 11c. The inner wall 11a is positioned on a boundary between the memory cell array region 1 and the STI region 3. The inner wall 11b is positioned on a boundary between the peripheral circuit region 2 and the STI region 3. As shown in FIG. 1B, the inner walls 11a and 11b are in contact with the insulating film 23. Particularly the entire inner wall 11b positioned on the side of the peripheral circuit region 2 is covered with the insulating film 23 without being exposed.

A manufacturing method of the semiconductor device according to the present embodiment is explained next.

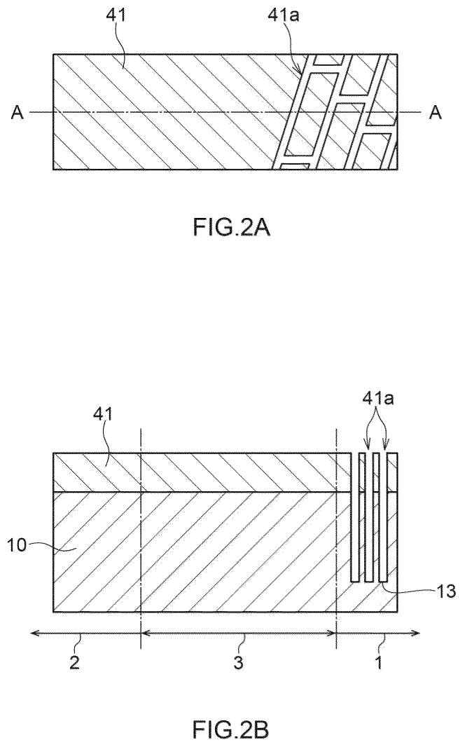

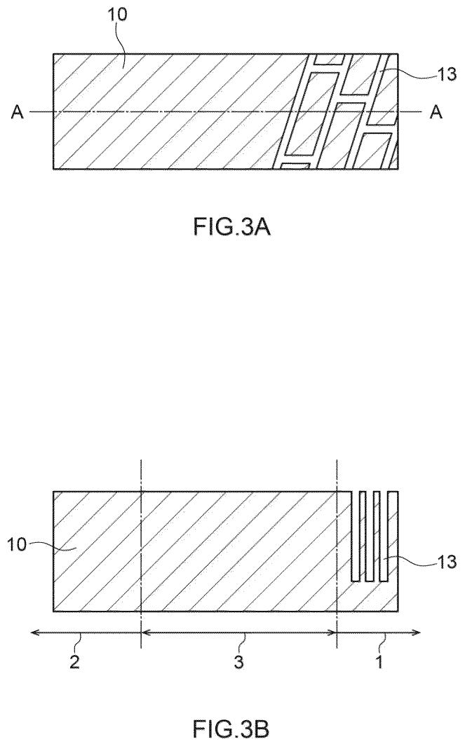

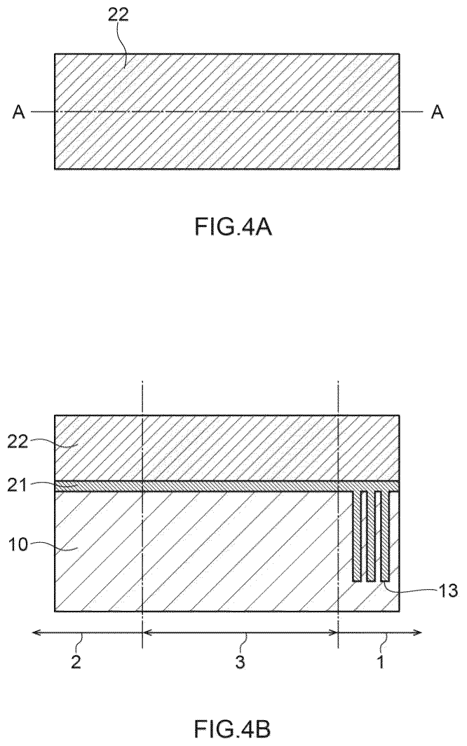

First, a hardmask 41 is formed on the semiconductor substrate 10 and the hardmask 41 is patterned to form openings 41a on the hardmask 41 as shown in FIGS. 2A and 2B. The semiconductor substrate 10 is then etched using the hardmask 41 as a mask, thereby forming a plurality of trenches 13 in the memory cell array region 1. Next, after the hardmask 41 is removed as shown in FIGS. 3A and 3B, the insulating film 21 and an insulating film 22 are formed in this order on the surface of the semiconductor substrate 10 as shown in FIGS. 4A and 4B. The insulating films 21 and 22 include a silicon oxide and a silicon nitride, respectively, and can be deposited by a CVD (Chemical Vapor Deposition) method. The film thickness of the insulating film 22 may be greater than that of the insulating film 21. The inner parts of the trenches 13 are thereby filled with the insulating film 22 including a silicon oxide. Cell transistors of a DRAM are formed in regions separated by the trenches 13.

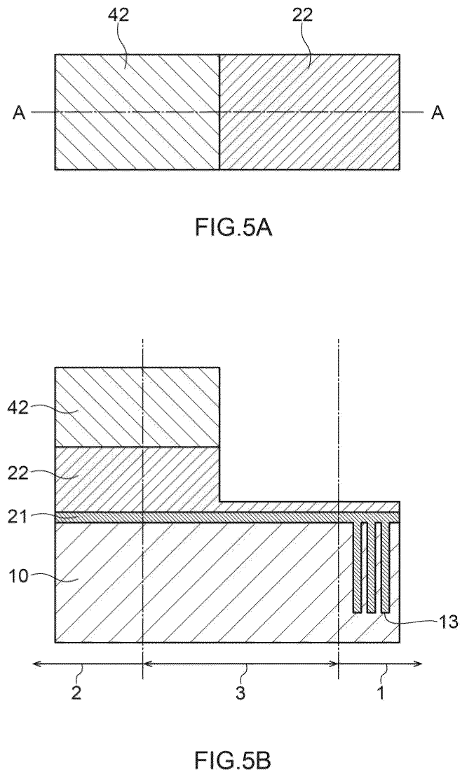

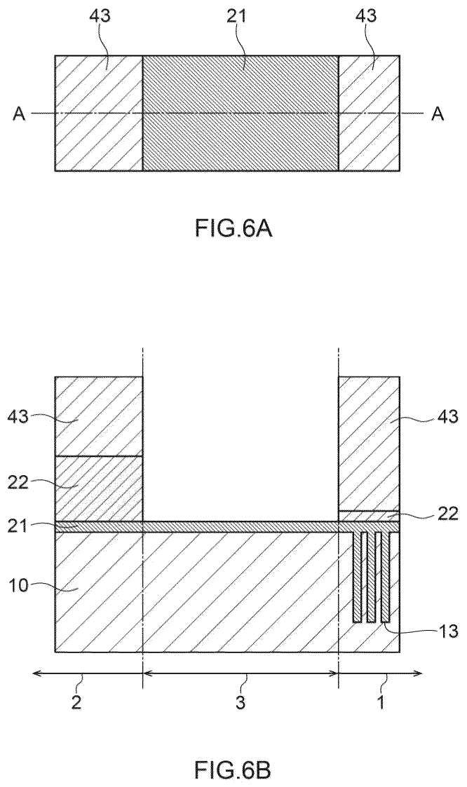

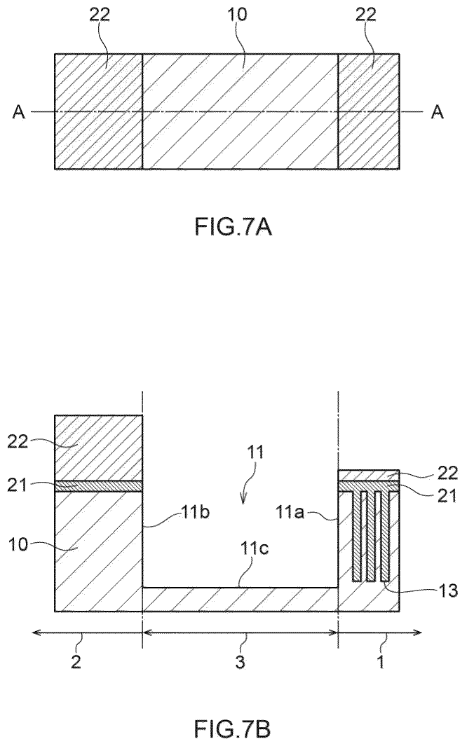

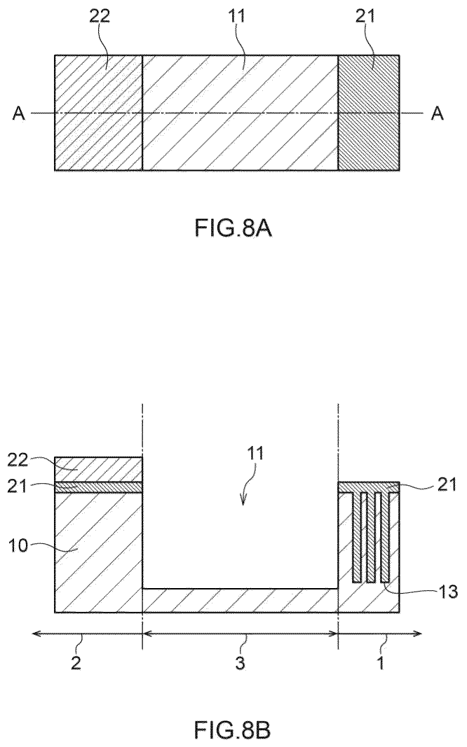

Next, as shown in FIGS. 5A and 5B, a portion of the insulating film 22 positioned in the peripheral circuit region 2 is covered with a resist 42 and the insulating film 22 is etched using the resist 42 as a mask, thereby decreasing the film thickness of a portion of the insulating film 22 positioned in the memory cell array region 1. Accordingly, the film thickness of the insulating film 22 on the memory cell array region 1 is smaller than that of the insulating film 22 on the peripheral circuit region 2. The edge of the resist 42 is positioned in the STI region 3 and a step is accordingly formed in the insulating film 22 on the STI region 3. Next, after the resist 42 is removed, another resist 43 covering the memory cell array region 1 and the peripheral circuit region 2 is formed as shown in FIGS. 6A and 6B. The insulating film 22 is then etched using the resist 43 as a mask, thereby removing a portion of the insulating film 22 covering the STI region 3 to expose the insulating film 21. Next, after the resist 43 is removed, the insulating film 21 and the semiconductor substrate 10 are etched using the insulating film 22 as a mask, thereby forming the trench 11 in the STI region 3 as shown in FIGS. 7A and 7B. Accordingly, the inner wall 11a positioned on the side of the memory cell array region 1, the inner wall 11b positioned on the side of the peripheral circuit region 2, and the bottom surface 11c are exposed in the trench 11. Thereafter, the silicon nitride is wet-etched so as to remove the insulating film 22 on the memory cell array region 1. Accordingly, the insulating film 21 is exposed on the memory cell array region 1 as shown in FIGS. 8A and 8B. At this time, the condition of the wet etching is set to prevent the insulating film 22 on the peripheral circuit region 2 from being completely removed.

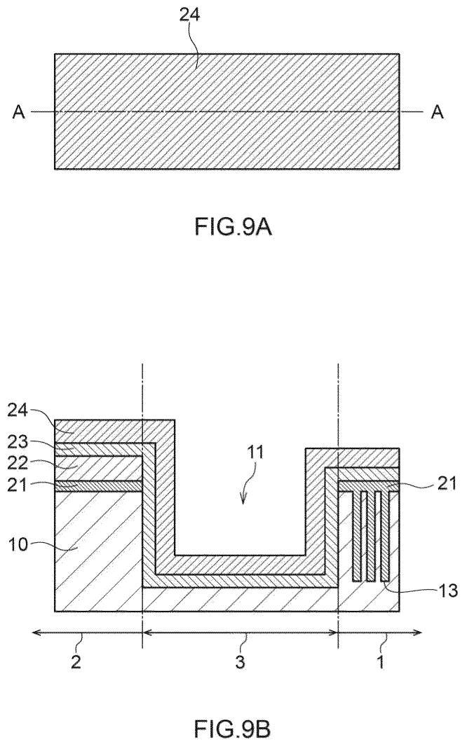

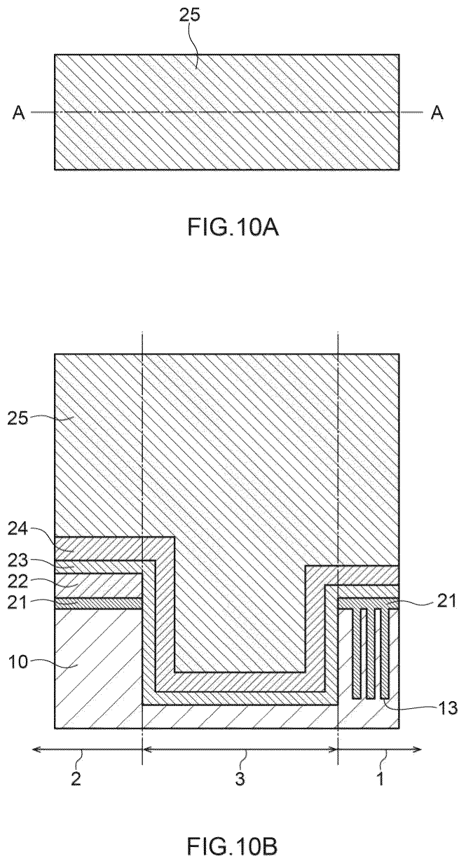

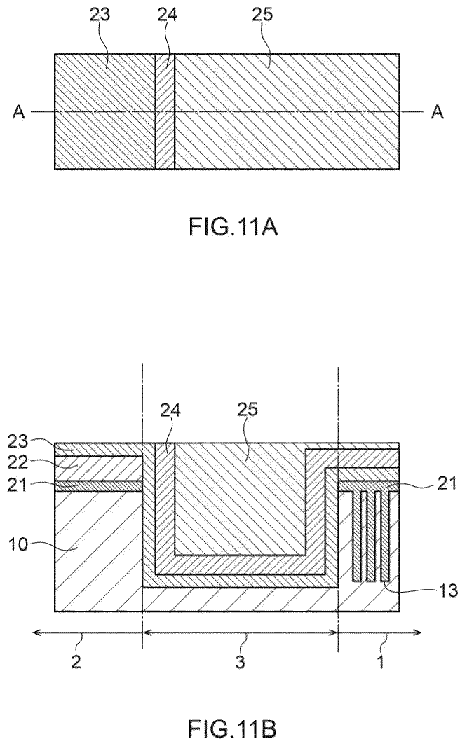

Next, the insulating films 23 and 24 are formed in this order all over the semiconductor substrate 10 as shown in FIGS. 9A and 9B. The insulating films 23 and 24 include a silicon oxide and a silicon nitride, respectively, and can be deposited by the CVD method. The film thicknesses of the insulating films 23 and 24 are set to such thicknesses that do not completely fill the trench 11. Accordingly, the memory cell array region 1, the peripheral circuit region 2, and the inner walls of the trench 11 are covered with a stacked film including the insulating films 23 and 24. Since the insulating film 22 has been removed on the memory cell array region 1 at this time, the insulating film 23 and the insulating film 21 are directly stacked without the insulating film 22 interposed therebetween. In contrast thereto, since the insulating film 22 remains on the peripheral circuit region 2, the insulating film 21 and the insulating film 23 are stacked with the insulating film 22 interposed therebetween. Next, the insulating film 25 including a SOG material is formed all over the semiconductor substrate 10 as shown in FIGS. 10A and 10B. The thickness of the insulating film 25 is set to a sufficient thickness to fill the trench 11 with the insulating film 25. Next, the insulating film 25 is polished by a CMP (Chemical Mechanical Polishing) method to expose the insulating film 23 on the peripheral circuit region 2 as shown in FIGS. 11A and 11B. Specifically, after CMP is performed using the insulating film 24 including a silicon nitride on the peripheral circuit region 2 as a stopper, CMP is performed in a state where there is no selectivity between a silicon nitride and a silicon oxide, and the CMP is ended at a time when the insulating film 23 including a silicon oxide is exposed. Accordingly, a state in which the insulating film 24 is removed on the peripheral circuit region 2 and the insulating film 24 is left on the memory cell array region 1 is obtained.

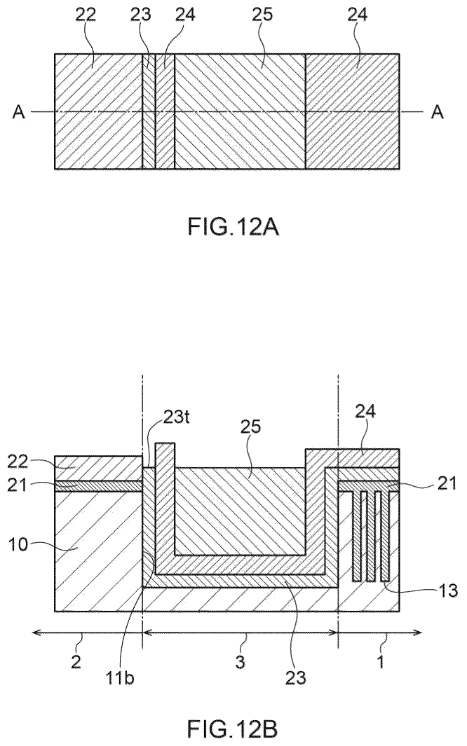

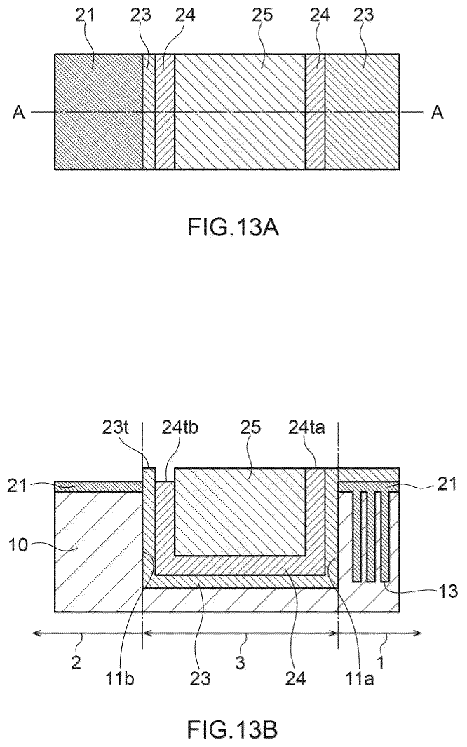

Next, dry etching is performed in a condition in which the etching rate to a silicon oxide is higher as shown in FIGS. 12A and 12B. This removes the insulating film 25 on the memory cell array region 1 to expose the insulating film 24 including a silicon nitride, and removes the insulating film 23 on the peripheral circuit region 2 to expose the insulating film 22 including a silicon nitride. At this time, the etching condition is set to cause a top surface 23t of the insulating film 23 covering the inner wall 11b of the trench 11 to be higher than the upper surface of the insulating film 21. Next, dry etching is performed in a condition in which the etching rate to a silicon nitride is higher as shown in FIGS. 13A and 13B. This removes the insulating film 24 on the memory cell array region 1 to expose the insulating film 23 including a silicon oxide, and removes the insulating film 22 on the peripheral circuit region 2 to expose the insulating film 21 including a silicon oxide. As a result, the insulating film 23 covering the inner wall 11b of the trench 11 is brought to a state in which the top surface 23t is protruded from the surface of the insulating film 21. A top surface 24tb of a portion of the insulating film 24 covering the inner wall 11b is lower than a top surface 24ta of a portion thereof covering the inner wall 11a. The upper surface of the insulating film 23 on the memory cell array region 1 and the upper surface of the insulating film 25 on the STI region 3 are substantially in a same plane.

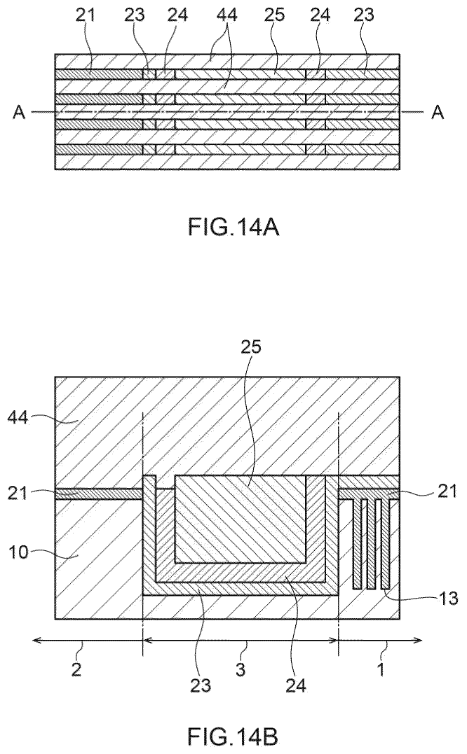

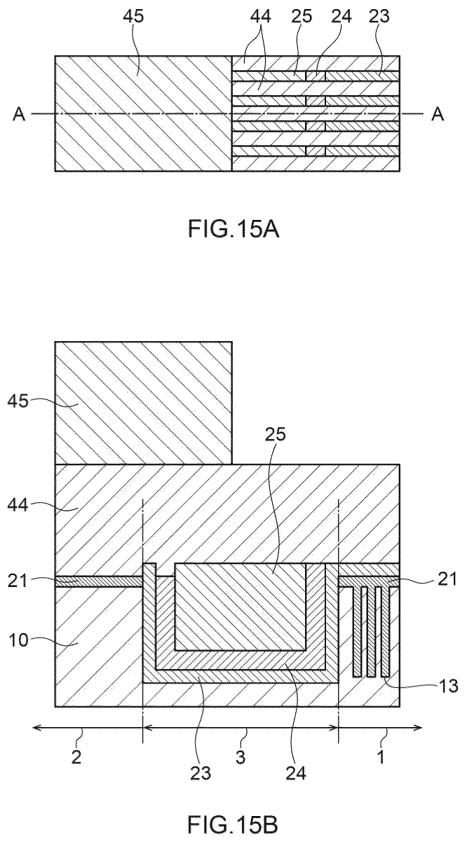

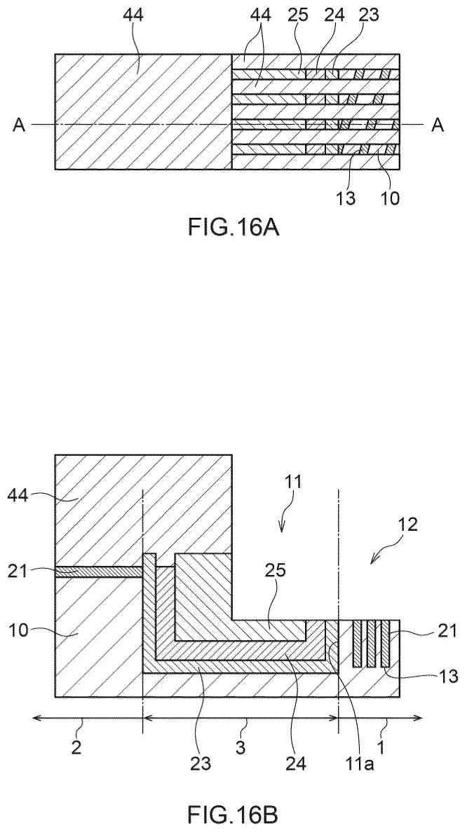

Next, after a hardmask 44 is formed all over the semiconductor substrate 10 as shown in FIGS. 14A and 14B, openings in the manner of stripes are formed on the hardmask 44. Next, the hardmask 44 formed on the peripheral circuit region 2 is covered with a resist 45 as shown in FIGS. 15A and 15B. The hardmask 44 formed on the memory cell array region 1 is in a state exposed without being covered with the resist 45. The edge of the resist 45 is positioned on the STI region 3. Next, after the resist 45 is removed, dry etching using the hardmask 44 as a mask is performed in this state, whereby a plurality of trenches 12 are formed in the memory cell array region 1 as shown in FIGS. 16A and 16B. This dry etching is performed in a condition in which differences in the selectivity among silicon, a silicon oxide, and a silicon nitride are small. Therefore, the insulating films 21 and 23 including a silicon oxide and the insulating film 24 including a silicon nitride are also etched, and the trenches 12 contact the trench 11 at the inner wall 11a. Since the upper surface of the insulating film 23 on the memory cell array region 1 and the upper surface of the insulating film 25 on the STI region 3 constitute substantially same planes at this time as shown in FIG. 13B, the widths of the trenches 12 formed in the memory cell array region 1 and the widths of the trenches 12 formed in the STI region 3 will be substantially uniform. That is, if there is a difference between the height of the upper surface of the insulating film 23 on the memory cell array region 1 and the height of the upper surface of the insulating film 25 on the STI region 3, the widths of the trenches 12 adversely change at a boundary portion between the memory cell array region 1 and the STI region 3. However, when the height of the upper surface of the insulating film 23 on the memory cell array region 1 and the height of the upper surface of the insulating film 25 on the STI region 3 are substantially equal, such a change in the widths of the trenches 12 can be prevented.

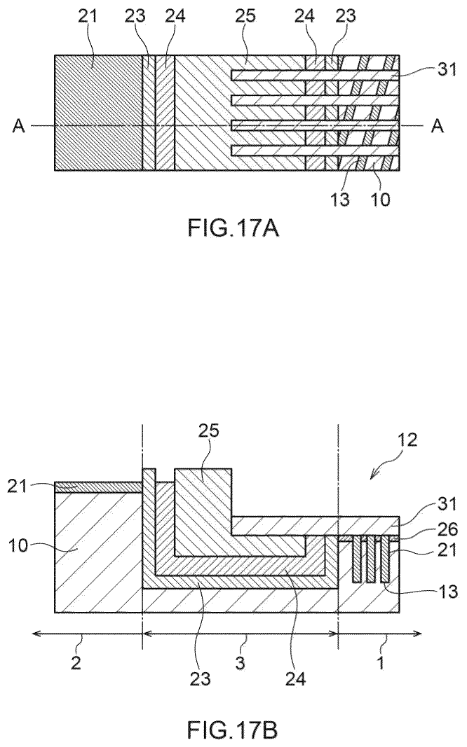

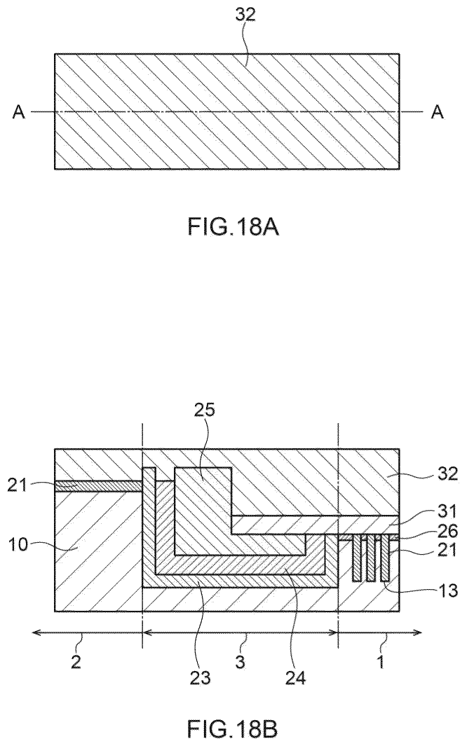

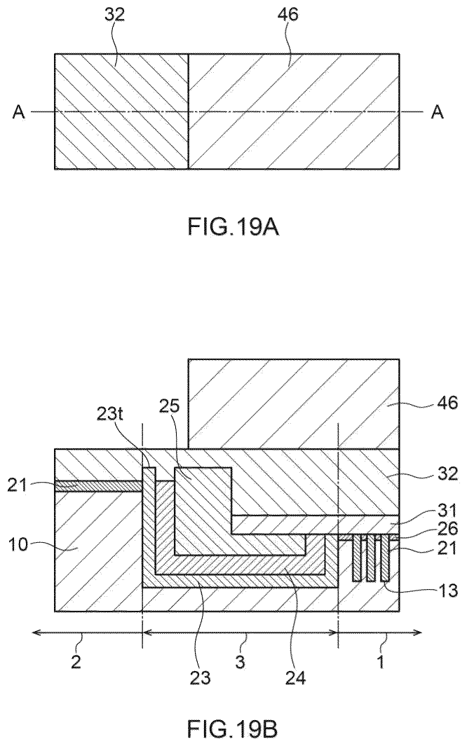

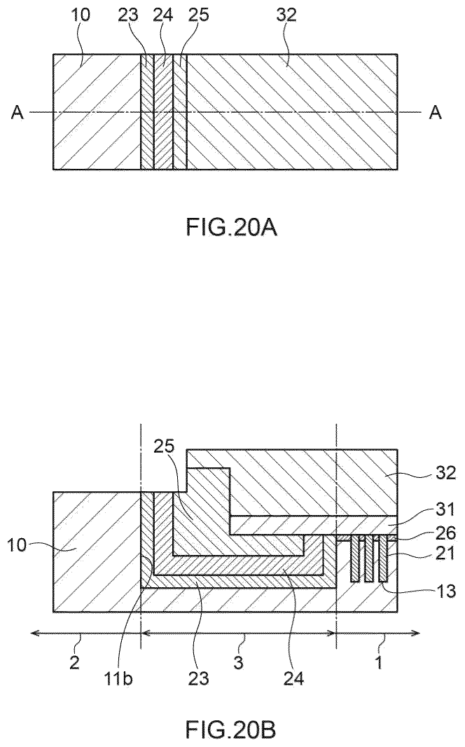

Next, after the hardmask 44 is removed as shown in FIGS. 17A and 17B, the semiconductor substrate 10 exposed on inner walls of the trenches 12 is thermally oxidized to form a silicon oxide film 26. This silicon oxide film 26 functions as gate electrodes of the cell transistors. The word line 31 is thereafter embedded in the trenches 12. Next, upper parts of the word lines 31 are covered with the insulating film 32 as shown in FIGS. 18A and 18B. Since the width of each of the trenches 12 is substantially uniform, breaking or the like of the word lines 31 due to a decrease in the widths of the trenches 12 relative to a design value does not occur. Next, the memory cell array region 1 is covered with a resist 46 as shown in FIGS. 19A and 19B. The peripheral circuit region 2 is in an exposed state without being covered with the resist 46. The edge of the resist 46 is positioned on the STI region 3. Next, etching is performed using the resist 46 as a mask, thereby removing the insulating films 21 and 32 formed on the peripheral circuit region 2 as shown in FIGS. 20A and 20B. Accordingly, the semiconductor substrate 10 is exposed in the peripheral circuit region 2. At this time, overetching needs to be performed so as to prevent the insulating film 21 from being left on the surface of the semiconductor substrate 10. However, since the insulating film 23 covering the inner wall 11b of the trench 11 is in a state in which the top surface 23t is protruded from the surface of the insulating film 21 in the present embodiment, the inner wall 11b of the trench 11 is not exposed and can be kept covered with the insulating film 21 even when the overetching to remove the insulating film 21 is performed.

Thereafter, when thermal oxidation processing is performed, the semiconductor substrate 10 exposed in the peripheral circuit region 2 is oxidated and the insulating film 33 is formed as shown in FIGS. 1A and 1B. Thereafter, a wiring pattern and the like are formed. Since the inner wall 11b of the trench 11 is not exposed and is kept covered with the insulating film 21 as described above, a metallic material constituting the wiring pattern and the like are not accumulated on the inner wall 11b of the trench 11.

Although this invention has been disclosed in the context of certain preferred embodiments and examples, it will be understood by those skilled in the art that the inventions extend beyond the specifically disclosed embodiments to other alternative embodiments and/or uses of the inventions and obvious modifications and equivalents thereof. In addition, other modifications which are within the scope of this invention will be readily apparent to those of skill in the art based on this disclosure. It is also contemplated that various combination or sub-combination of the specific features and aspects of the embodiments may be made and still fall within the scope of the inventions. It should be understood that various features and aspects of the disclosed embodiments can be combined with or substituted for one another in order to form varying mode of the disclosed invention. Thus, it is intended that the scope of at least some of the present invention herein disclosed should not be limited by the particular disclosed embodiments described above.

1. An apparatus comprising:
a semiconductor substrate including:
first and second circuit regions;
a first trench extending in a first direction and formed between the first and second circuit regions, wherein the first trench includes a first inner wall positioned on the first circuit region side and a second inner wall positioned on the second circuit region side; and
a plurality of second trenches extending in a second direction different from the first direction and formed in the first circuit region such that each of the plurality of second trenches contacts the first trench at the first inner wall; and
a first insulating film formed on the first and second inner walls such that a height of the first insulating film is equal to or greater than the second inner wall.

2. The apparatus of claim 1, further comprising a plurality of signal lines,
wherein each of the signal lines is at least partially embedded in an associated one of the second trenches.

3. The apparatus of claim 2, wherein a top part of each of the signal lines is covered with an insulating film.

4. The apparatus of claim 1, wherein a top end of the first insulating film formed on the second inner wall is positioned equal to or higher than a surface of the second circuit region.

5. The apparatus of claim 1, further comprising a second insulating film formed in the first trench such that the first insulating film is sandwiched between the second insulating film and the first and second inner walls,
wherein the second insulating film comprises a different insulating material from the first insulating film.

6. The apparatus of claim 5,
wherein the first insulating film comprises a silicon oxide, and
wherein the second insulating film comprises a silicon nitride.

7. The apparatus of claim 6,
wherein the second insulating film includes a first section covering the first inner wall and a second section covering the second inner wall, and
wherein a top end of the second section of the second insulating film is positioned higher than a top end of the first section of the second insulating film.

8. The apparatus of claim 6, further comprising a third insulating film filling the first trench such that the first and second insulating films are located between the third insulating film and the first and second inner walls,
wherein the third insulating film comprises a silicon oxide.

9. The apparatus of claim 8, wherein an upper surface of the first insulating film on the first inner wall and an upper surface of the third insulating film are in a same plane.

10. An apparatus comprising:
a semiconductor substrate including:
a first circuit region on which a plurality of memory cells is formed; and
an STI region adjacent to the first circuit region, the STI region comprising a trench extending in a first direction, wherein the first trench includes a first inner wall positioned on a boundary between the first circuit region and the STI region; and
a plurality of second trenches extending in a second direction different from the first direction over the first circuit region and the STI region such that each of the plurality of second trenches contacts the first trench at the first inner wall, wherein widths of the second trenches are uniform.

11. The apparatus of claim 10, further comprising: a second circuit region adjacent to the first trench opposite to the first circuit region, wherein the first trench further comprises a second inner wall on a boundary between the first trench and the second circuit region.

12. The apparatus of claim 11, further comprising a first insulating film covering the first inner wall, the second inner wall, and the first circuit region, wherein an entire second inner wall is covered with the first insulating film.

13. The apparatus of claim 12, further comprising a second insulating film on the first insulating film.

14. The apparatus of claim 13, further comprising:
a word line at least partially embedded in an associated one of the plurality of second trenches; and
a third insulating film configured to cover an upper part of the word line and at least a part of the second insulating film.

15. The apparatus of claim 12, wherein a top surface of the second circuit region is free from the first insulating film.

16. The apparatus of claim 10, wherein the first circuit region further comprises a plurality of third trenches, wherein an insulating film is embedded in at least inner parts of the plurality of third trenches.

17. The apparatus of claim 16, wherein the insulating film functions as a STI region for cell transistors of a DRAM.

18. A method comprising:
forming first then second insulating films on a semiconductor substrate over a first circuit region, a second circuit region, and a shallow trench isolation (STI) region between the first and second circuit regions;
forming a first trench in the STI region by selectively removing the first insulating film, the second insulating film, and a portion of the semiconductor substrate in the STI region, wherein the first trench comprises a first inner wall adjacent to the first circuit region side and a second inner wall adjacent to the second region side;
depositing a third insulating film then a fourth insulating film over the semiconductor substrate, wherein the third insulating film and the fourth insulating film are configured to partially fill the first trench;
depositing a fifth insulating film over the substrate, wherein the fifth insulating film is configured to fill the first trench; and
forming a plurality of second trenches in the first circuit region extending from the first circuit region to the STI region, wherein each of the plurality of second trenches contacts the first trench at the first inner wall, wherein the third insulating film, the fourth insulating film, and the fifth insulating film are selectively etched wherein an upper surface of the fifth insulating film on the STI region and an upper surface of the third insulating film on the first circuit region are at the same height.

19. The method of claim 18, further comprising:
removing the second insulating film in the first circuit region before depositing the third and fourth insulating films.

20. The method of claim 18, wherein widths of the plurality of second trenches in the first circuit region and widths of the plurality in the STI region are the uniform.
